(19) United States
(12) Patent Application Publication
(10) Pub. No.: US 2026/0282995 A1
(43) Pub. Date: Sep. 17, 2026

(54) SUBSTRATE ASSEMBLY WITH SURFACE STRUCTURE

(71) Applicant: HERAEUS ELECTRONICS GMBH & CO. KG, Hanau (DE)

(72) Inventors: Andreas HINRICH, Hanau (DE); Andreas Steffen KLEIN, Hanau (DE); Frank KRÜGER, Hanau (DE); Stefanie STOICA, Hanau (DE)

(21) Appl. No.: 19/471,939

(22) PCT Filed: Apr. 2, 2024
(86) PCT No.: PCT/EP2024/058894

§ 371 Date: Oct. 2, 2025

(30) Foreign Application Priority Data
Apr. 4, 2023 (EP) 23166548.0

(51) Int. Cl. H10W 72/90; H10W 72/00; H10W 72/59; H10W 90/00

(52) U.S. Cl. CPC H10W 72/923; H10W 72/01936; H10W 72/59; H10W 72/952; H10W 90/734

(57) ABSTRACT

A substrate arrangement and a method for producing an electronic assembly. The substrate arrangement has (a) a bonding substrate which comprises an upper side and an underside, and (b) a contacting layer which comprises a contacting means, wherein the contacting layer is connected to the underside of the bonding substrate in a planar manner at least in regions, wherein the underside of the bonding substrate (i) has an arithmetic mean roughness value R(1)ₐ along at least one section S1, and (ii) an arithmetic mean roughness value R(2)ₐ along at least one section S2, wherein the at least one section S2 runs perpendicularly to the at least one section S1, wherein the ratio Q of arithmetic mean roughness value R(1)ₐ to arithmetic mean roughness value R(2)ₐ is in the range of 1.70-10.00.

The present invention relates to a substrate arrangement and to a method for producing an electronic assembly.

In order to produce electronic assemblies, base substrates, in particular metal-ceramic substrates or leadframes, are often populated with electronic components, in particular semiconductors, in the field of power electronics.

Regions which have to be contacted electrically conductively with unpopulated regions of the base substrates are located on the upper side of the electronic components, which faces away from the base substrates. This contacting usually takes place with bonding wires, wherein one end of the bonding wire is integrally bonded to a region on the upper side of the electronic component, while the other end of the bonding wire is integrally bonded to an unpopulated region of the base substrate. Bonding wires made of aluminum can be integrally bonded to the metal of the base substrates, in particular copper. Bonding wires made of aluminum, for example via a metal, usually silver-containing layer, which is located on the upper side of the electronic components, can also be integrally bonded to the electronic components. However, bonding wires made of aluminum have the disadvantage of low electrical conductivity. Furthermore, it has been found that electrical contacting of electronic components and base substrates via bonding wires made of aluminum has only insufficient reliability and reduced functionality.

For this reason, there is a need to replace aluminum bonding wires with bonding wires made of copper. Copper has a very high electrical conductivity compared to aluminum. Furthermore, bonding wires made of copper can be connected particularly reliably in an integrally bonded manner to the metal of the base substrates, in particular copper. However, bonding wires made of copper cannot easily be connected to the upper side of the electronic components in an integrally bonded manner.

In the prior art, it is therefore proposed to not connect bonding wires made of copper directly to the upper side of the electronic components. Rather, a substrate arrangement is provided which has a bonding substrate and a contacting layer. The bonding substrate, usually a metal foil, has an upper side and an underside, wherein the underside of the bonding substrate is connected in a planar manner to the contacting layer, usually a pre-dried sintering paste. The bonding substrate of the substrate arrangement is lastly integrally bonded to the upper side of the electronic component via the contacting layer, so that the upper side of the bonding substrate is available for an integrally bonded connection to the copper bonding wire.

A reliable connection of a bonding wire to the upper side of an electronic component via a substrate arrangement requires that the bonding substrate can be connected to the upper side of the electronic component in a stable and integrally bonded manner via the contacting layer.

There is thus a need for a substrate arrangement with which the bonding substrate can be connected in a particularly stable and integrally bonded manner to the upper side of the electronic component via the contacting layer.

Therefore, an object of the present invention is preferably to provide a substrate arrangement which enables a stable integrally bonded connection between the bonding substrate and the upper side of the electronic component via the contacting layer.

This object is achieved by the substrate arrangement according to claim 1.

The invention therefore provides a substrate arrangement comprising
(a) a bonding substrate comprising an upper side and an underside, and
(b) a contacting layer which comprises a contacting means, wherein the contacting layer is connected in a planar manner to the underside of the bonding substrate at least in regions,
wherein the underside of the bonding substrate
(i) has an arithmetic mean roughness value R(1)ₐ along at least one section S1, and
(ii) has an arithmetic mean roughness value R(2)ₐ along at least one section S2, wherein the at least one section S2 runs perpendicularly to the at least one section S1,
wherein the ratio Q of arithmetic mean roughness value R(1)ₐ to arithmetic mean roughness value R(2)ₐ is in the range of 1.70-10.00.

In addition, the invention provides a method for producing an electronic assembly.

The invention relates to a substrate arrangement.

The electrical contacting of the upper side of an electronic component with unpopulated regions of base substrates can preferably be prepared with the substrate arrangement. For this purpose, the bonding substrate is connected in an integrally bonded manner to the upper side of the electronic component via the contacting layer. The bonding substrate in this case provides a surface which is suitable for forming a reliable integrally bonded connection to one end of a bonding wire, in particular a copper bonding wire. The other end of the bonding wire can be connected to an unpopulated region of a base substrate, so that an electrical contacting results between the upper side of the electronic component and an unpopulated region of a base substrate via the bonding substrate and the bonding wire. The upper side of the substrate arrangement is therefore connectable to a bonding wire. Preferably, the substrate arrangement does not have a layer of an insulating material, in particular no ceramic layer. Particularly preferably, the substrate arrangement does not have an insulating material, in particular no ceramic.

The substrate arrangement has a bonding substrate.

The bonding substrate comprises an upper side and an underside. The underside of the bonding substrate is preferably the surface of the bonding substrate with the greatest surface area which is connected in a planar manner to the contacting layer at least in regions. The upper side of the bonding substrate is therefore preferably the side of the bonding substrate facing away from the contacting layer. The upper side of the bonding substrate is consequently the side opposite the underside of the bonding substrate. The bonding substrate preferably has a thickness in the range of 5-500 μm, particularly preferably a thickness in the range of 10-450 μm, and very particularly preferably a thickness in the range of 20-400 μm.

According to a preferred embodiment, the bonding substrate comprises a metal foil. Very particularly preferably, the bonding substrate is a metal foil.

The metal foil preferably comprises at least one element which is selected from the group consisting of metals and metal alloys. According to a further preferred embodiment, the metal foil comprises at least one element which is selected from the group consisting of copper and copper alloys. According to a particularly preferred embodiment, the metal foil comprises copper. It may be preferred here that copper alloys are alloys of copper with at least one further metal selected from the group consisting of nickel, tin, iron, silver, tungsten, and molybdenum.

According to a preferred embodiment, the metal foil comprises a main body. The term “main body” is preferably understood herein to mean a coating-free metal foil. The main body preferably comprises at least one element which is selected from the group consisting of metals and metal alloys. According to a further preferred embodiment, the main body comprises at least one element which is selected from the group consisting of copper and copper alloys. According to a particularly preferred embodiment, the main body comprises copper. It may be preferred here that copper alloys are alloys of copper with at least one further metal selected from the group consisting of nickel, tin, iron, silver, tungsten, and molybdenum.

According to a particularly preferred embodiment, the metal foil is formed from the main body. According to this embodiment, it can accordingly be provided that the bonding substrate is an uncoated copper foil. According to this particularly preferred embodiment, the underside of the bonding substrate is created by the metal foil and the upper side of the bonding substrate is created by the metal foil. Accordingly, the underside of the bonding substrate is created by the main body and the upper side of the bonding substrate is created by the main body.

According to a further particularly preferred embodiment, the metal foil comprises a main body and a coating. The coating is preferably arranged here on the main body. The coating preferably comprises a noble metal. The noble metal is preferably selected from the group consisting of gold, silver and palladium. The coating preferably comprises at least one first layer containing a noble metal, wherein the first layer containing the noble metal is connected to the contacting layer in a planar manner at least in regions. The first layer can be formed from a noble metal or a noble metal alloy. The noble metal alloy is preferably an alloy which contains at least one noble metal and at least one non-noble metal. The non-noble metal of the noble metal alloy is preferably nickel. The noble metal alloy is preferably selected from the group consisting of nickel-gold alloys, nickel-silver alloys, and nickel-palladium-gold alloys. According to a preferred embodiment, the coating comprises at least one further layer. The at least one further layer is preferably connected to the first layer in a planar manner. The at least one further layer is preferably not connected to the contacting layer in a planar manner. According to a preferred embodiment, the at least one further layer comprises a noble metal or a non-noble metal. The non-noble metal is preferably nickel. The at least one further layer can be formed from a noble metal, a noble metal alloy or a non-noble metal alloy (an alloy comprising no noble metal). The noble metal alloy is preferably an alloy which contains at least one noble metal and at least one non-noble metal. According to a particularly preferred embodiment, the coating comprises a first layer containing gold, a second layer containing palladium and a third layer containing nickel, in particular a first layer of gold, a second layer of palladium and a third layer of nickel. In this case, the third layer is preferably connected in a planar manner to the contacting layer at least in regions, the second layer is connected in a planar manner to the third layer and the first layer at least in regions, and the first layer is connected in a planar manner to the second layer and the main body at least in regions. According to a very particularly preferred embodiment, the first layer has a thickness in the range of 10-150 nm, the second layer has a thickness in the range of 50-200 nm, and the third layer has a thickness in the range of 1-5 μm. The coating of the metal foil is preferably coated by electroplating or chemical deposition. According to this embodiment, the underside of the bonding substrate is created by the coating. In this case, the underside of the bonding substrate is preferably created by the coating and the upper side of the bonding substrate is created by the main body.

Consequently, the bonding substrate preferably comprises a metal foil which comprises a main body on which a coating can be arranged, wherein the underside of the bonding substrate (i) is created by the main body when no coating is arranged on the main body, and (ii) is created by the coating when there is a coating arranged on the main body.

According to a further preferred embodiment, the bonding substrate is not connected in an integrally bonded manner to an insulating material, in particular is not connected in an integrally bonded manner to a ceramic material.

According to a further preferred embodiment, the bonding substrate has at least one through-opening from the upper side to the underside. A through-opening is preferably understood to mean a recess in the material of the bonding substrate which extends from a first opening on the upper side of the bonding substrate up to a second opening on the underside of the bonding substrate. The openings can have different sizes and geometries. It can be preferred that the bonding substrate has a plurality of through-openings. The through-openings can, for example, be cylindrical, round, rectangular, oval, elliptical or rectangular with rounded corners. The presence of through-openings can be advantageous in particular if the substrate arrangement comprises a prefixing layer which contains a prefixing agent. In this case, components or residues of the prefixing agent can liquefy during a temperature application or pressure application, such as during a sintering process, and can be absorbed into the through-openings due to the capillary effect caused by the through-opening in order thereby to avoid an uncontrollable escape of the portions or residues of the prefixing agent.

According to yet another embodiment, the bonding substrate has no or only a few recesses in the upper side of the metal foil, and in particular no recesses or only a few recesses which extend from the upper side to the underside of the metal foil. Preferably, the proportion of recesses in the upper side of the metal foil is less than 10%, more preferably less than 5%, particularly preferably less than 1%, very particularly preferably less than 0.1%, and in particular less than 0.01%, relative to the total area of the upper side of the metal foil. Particularly preferably, the proportion of recesses in the upper side of the metal foil which extend from the upper side to the underside of the metal foil is less than 10%, more preferably less than 5%, particularly preferably less than 1%, very particularly preferably less than 0.1%, and in particular less than 0.01%, relative to the total area of the upper side of the metal foil. The total area of the upper side of the metal foil is preferably understood to mean the surface of the upper side of the metal foil which is occupied by metal and the recesses.

According to a further preferred embodiment, the upper side of the substrate arrangement is created by the bonding substrate.

The substrate arrangement has a contacting layer.

The contacting layer is a layer which is connected in a planar manner at least in regions to the underside of the bonding substrate.

According to a preferred embodiment, the contacting layer is connected to the underside of the bonding substrate in a planar manner such that at least 75%, more preferably at least 90%, particularly preferably at least 95%, very particularly preferably at least 98% and in particular 100%, of the area occupied by the underside of the bonding substrate is provided with contacting layer.

The contacting layer preferably has a layer thickness in the range of 5-500 μm, particularly preferably a layer thickness in the range of 5-100 μm, and very particularly preferably a layer thickness in the range of 10-50 μm.

The contacting layer comprises a contacting means. The contacting means is preferably able to enter into an integrally bonded connection with an electronic component, in particular the optionally metallized upper side of an electronic component.

According to a preferred embodiment, the contacting means comprises at least one element which is selected from the group consisting of sintering materials, solder materials, and adhesives.

The sintering material is preferably selected from the group consisting of sintering pastes, sintering films and sintering preforms. The sintering material preferably comprises at least one element which is selected from the group consisting of silver and copper. According to a particularly preferred embodiment, the sintering material comprises silver.

According to a preferred embodiment the sintering material comprises a sintering paste. The sintering paste is preferably a sintering paste customary in the art. The sintering paste preferably comprises at least one element which is selected from the group consisting of silver and copper, and an organic compound. It can be preferred that the at least one element which is selected from the group consisting of silver and copper, particularly preferably silver, is present in the sintering paste in the form of particles. The particles can assume any shape and can therefore be present, for example, as spherical particles, flakes or irregularly shaped particles. The organic compound is preferably selected from the group consisting of dispersants, binders, fatty acids, and mixtures thereof. The dispersant can be selected from dispersants that are customary in the art. An exemplary dispersant is Terpineol. The binders can be selected from polymers that are customary in the art. Examples include cellulose derivatives, for example methylcellulose, ethylcellulose, ethylmethylcellulose, carboxycellulolose and hydroxypropylcellulolose. The fatty acids can be selected from fatty acids that are customary in the art. The fatty acids are preferably selected from the group consisting of caprylic acid (octanoic acid), capric acid (decanoic acid), lauric acid (dodecanoic acid), myristic acid (tetradecanoic acid), palmitic acid (hexadecanoic acid), margaric acid (heptadecanoic acid), stearic acid (octadecanoic acid), arachidic acid (eicosanoic acid/icosanoic acid), behenic acid (docosanoic acid) and lignoceric acid (tetracosanoic acid). The sintering paste is preferably pre-dried. The pre-drying can serve to at least partially remove volatile constituents contained in the sintering paste, such as organic compound, for example. The pre-drying can take place, for example, at a temperature in the range of 80-150° C. and, for example, for a period of 2-30 minutes.

According to a further preferred embodiment, the sintering material comprises a sintering film. Preferably, the sintering film is a sintering film customary in the art, as disclosed, for example, in European patent application EP3154729 A1. A sintering film can therefore have, for example, a sintering paste which comprises metal particles (in particular silver particles) and a binder which is present pre-dried on a carrier substrate. The sintering film can, for example, have a thickness in the range of 5-300 μm.

According to a further preferred embodiment, the sintering material comprises a sintering preform. Preferably, the sintering preform is a conventional sintering preform as disclosed, for example, in European patent application EP2428293 A2.

According to a further preferred embodiment, the solder material comprises at least one solder paste. The solder paste is preferably a solder paste customary in the art. The solder paste preferably comprises a solder alloy and a flux. The solder alloy preferably comprises, as the main element (element having the greatest weight proportion), tin, particularly preferably at least one further element which is selected from the group consisting of copper and silver, and very particularly preferably at least one further element which is selected from the group consisting of bismuth, antimony, indium, germanium, cobalt, iron and nickel. The flux is preferably a flux customary in the art, particularly preferably an organic flux.

According to a further preferred embodiment, the adhesive comprises a conductive adhesive. The conductive adhesive is preferably a conductive adhesive customary in the art. The conductive adhesive preferably comprises silver particles and an epoxy resin, which preferably cures at a temperature in the range of 120° C.-200° C.

According to a preferred embodiment, the substrate arrangement comprises a prefixing layer.

The prefixing layer is preferably a layer which is connected to at least one further side. The prefixing layer can be, for example, a continuous layer or an interrupted layer. The dimension of the continuous layer is not further limited. Therefore, the continuous layer also comprises a punctiform layer. In the case of a continuous layer, the prefixing layer can be connected to the at least one further side in a planar manner. In the case of an interrupted layer, the prefixing layer can comprise a plurality of portions which are not in contact with one another and which are connected in a planar manner to the at least one further side. The at least one further side is preferably a side of the contacting layer or a side of the bonding substrate. According to a preferred embodiment, the prefixing layer is a layer which is connected (i) to the underside of the bonding substrate, (ii) to the side of the contacting layer facing away from the bonding substrate or (iii) to the underside of the bonding substrate and to the side of the contacting layer facing away from the bonding substrate. If the prefixing layer is connected to the underside of the bonding substrate, the contacting layer is preferably connected in a planar manner to the underside of the bonding substrate, and the prefixing layer is connected to regions of the underside of the bonding substrate which are not connected in a planar manner to the contacting layer. In this case, the contacting layer and the prefixing layer are each connected to the underside of the bonding substrate and are preferably arranged next to one another.

According to a preferred embodiment, the prefixing layer is formed as a continuous layer and is connected in a planar manner to the side of the contacting layer facing away from the bonding substrate, so that at least 20%, more preferably at least 50%, particularly preferably at least 70%, very particularly preferably at least 98% and in particular 100% of the area of the side of the contacting layer facing away from the bonding substrate is in contact with the prefixing layer.

According to a further preferred embodiment, the prefixing layer is formed as a continuous layer in a punctiform manner and is in contact with the side of the contacting layer facing away from the bonding substrate and/or with the underside of the bonding substrate.

According to a further preferred embodiment, the prefixing layer is formed as an interrupted layer comprising a plurality of portions which are not in contact with one another and which are in contact with the side of the contacting layer facing away from the bonding substrate and/or with the underside of the bonding substrate.

The prefixing layer preferably comprises a prefixing agent. The prefixing agent can serve to prefix the substrate arrangement on an electronic component so that the structure comprising the substrate arrangement and the electronic component has improved transportability—for example, at the location of the further processing. Preferably, the prefixing agent is a temporary or releasable fixing agent which allows at least a temporary fixing of the substrate arrangement to an electronic component. Suitable prefixing agents are described, for example, in European patent application EP3940758 A2.

The prefixing agent therefore preferably comprises at least one compound which is selected from the group consisting of thermoplastic polymers, inorganic filler particles, and organic solvents. According to a preferred embodiment, the prefixing agent comprises at least one thermoplastic polymer and particularly preferably at least one compound which is selected from the group consisting of inorganic filler particles and organic solvents.

The thermoplastic polymers preferably have a glass transition temperature in the range of 60-120° C. The glass transition temperature is preferably determined by means of dynamic differential calorimetry (DDC) or by means of differential scanning calorimetry (DSC) at a heating rate of 10° C./minute. The thermoplastic polymers can in particular be (meth)acrylic copolymers. The (meth)acrylic copolymers preferably have a molar mass in the range of 35,000-70,000 g/mol (Mw=35,000 to 70,000 g/mol). The molar mass is preferably determined by means of gel permeation chromatography (GPC). For the gel permeation chromatography, the following applies: polystyrene gel as stationary phase, tetrahydrofuran as mobile phase, polystyrene standards.

The inorganic filler particles are preferably particles comprising at least one element selected from the group consisting of aluminum oxide, silicon dioxide, titanium dioxide, zirconium silicate, calcium silicate, mica, kaolin, and α-boron nitride. The inorganic filler particles preferably have an average particle size (d50) in the range of 5-20 μm and particularly preferably in the range of 5-10 μm. The average particle size (d50) is preferably determined by means of a laser diffraction method.

The organic solvents preferably have a boiling point of not more than 285° C. According to a preferred embodiment, the organic solvents are selected from the group consisting of aromatics, ketones, esters, glycol ethers and alcohols. According to a particularly preferred embodiment, the organic solvents are selected from the group consisting of toluene, xylene, methyl ethyl ketone, methyl isobutyl ketone, ethyl acetate, isobutyl acetate, dimethyl succinate, diethylene glycol monobutyl ether, benzyl alcohol, and terpineols. According to a very particularly preferred embodiment, the organic solvents are selected from the group of terpineols.

According to a further preferred embodiment, the underside of the substrate arrangement is created by the contacting layer or the prefixing layer.

The underside of the bonding substrate has
(i) has an arithmetic mean roughness value R(1)ₐ along at least one section S1, and
(ii) has an arithmetic mean roughness value R(2)ₐ along at least one section S2, wherein the at least one section S2 runs perpendicularly to the at least one section S1,
wherein the ratio Q of arithmetic mean roughness value R(1)ₐ to arithmetic mean roughness value R(2)ₐ is in the range of 1.70-10.00.

The mean roughness value is a measured variable of the roughness of a surface; it is determined over a section. Ra stands for the arithmetic mean roughness value according to the standard DIN EN ISO 4287. Here, the mean roughness value R(1)ₐ describes the arithmetic mean of the absolute height values along at least one section S1 and the mean roughness value R(2)ₐ describes the arithmetic mean of the absolute height values along at least one section S2, wherein the at least one section S2 runs perpendicularly to the at least one section S1. Determining the mean roughness value R(1)ₐ and the mean roughness value R(2)ₐ is accordingly preferably carried out according to the version of DIN EN ISO 4287 valid on the filing date.

The underside of the bonding substrate has an arithmetic mean roughness value R(1)ₐ along at least one section S1.

The arithmetic mean roughness value R(1)ₐ is determined along at least one section S1. The arithmetic mean roughness value R(1)ₐ is preferably determined along a plurality of sections S1.

The arithmetic mean roughness value R(1)ₐ is particularly preferably determined along a plurality of sections S1 which run parallel to one another. Very particularly preferably, the arithmetic mean roughness value R(1)ₐ is determined along at least ten sections S1 which run in parallel with one another. The at least one section S1 preferably has a length of at least 20% and particularly preferably a length of at least 25% of the circumference of the bonding substrate. Preferably, the bonding substrate has two opposite edges Rd1a and Rd1b running in parallel with one another, which are spaced apart by the section S(Rd)1, wherein the length of the at least one section S1 comprises at least 50% of the length of the section S(Rd)1, more preferably at least 75% of the length of the section S(Rd)1, particularly preferably at least 90% of the length of the section S(Rd)1, very particularly at least 95% of the length of the section S(Rd)1, and in particular the entire length of the section S(Rd)1. In the event that the arithmetic mean roughness value R(1)ₐ is determined along a plurality of sections S1, the figures relate to the length of the at least one section S1 preferably relate to the average length.

The underside of the bonding substrate has an arithmetic mean roughness value R(2)ₐ along at least one section S2, wherein the at least one section S2 runs perpendicularly to the at least one section S1.

The arithmetic mean roughness value R(2)ₐ is determined along at least one section S2. The arithmetic mean roughness value R(2)ₐ is preferably determined along a plurality of sections S2. The arithmetic mean roughness value R(2)ₐ is particularly preferably determined along a plurality of sections S2 which run parallel to one another. Very particularly preferably, the arithmetic mean roughness value R(2)ₐ is determined along at least ten sections S2 which run in parallel with one another. The at least one section S2 runs perpendicularly to the at least one section S1. The at least one section S2 preferably has a length of at least 50%, particularly preferably a length of at least 60%, and very particularly preferably a length of at least 70% of the length of the at least one section S1. In the event that the arithmetic mean roughness values R(1)ₐ and R(2)ₐ are determined along a plurality of sections S1 and S2, the sections S2 have an average length of at least 50%, particularly preferably of at least 60%, and very particularly preferably of at least 70% of the average length of the sections S1. Preferably, the bonding substrate has two opposite edges Rd2a and Rd2b running in parallel with one another, which are spaced apart by the section S(Rd)2, wherein the section S(Rd)2 runs perpendicularly to the section S(Rd)1. The length of the at least one section S2 preferably comprises at least 50% of the length of the section S(Rd)2, more preferably at least 75% of the length of the section S(Rd)2, particularly preferably at least 90% of the length of the section S(Rd)2, very particularly at least 95% of the length of the section S(Rd)2, and in particular the entire length of the section S(Rd)2. In the event that the arithmetic mean roughness value R(2)ₐ is determined along a plurality of sections S2, the figures relate to the length of the at least one section S2 preferably relate to the average length.

The ratio Q of arithmetic mean roughness value R(1)ₐ to arithmetic mean roughness value R(2)ₐ is in the range of 1.70-10.00.

Preferably, the ratio Q of arithmetic mean roughness value R(1)ₐ to arithmetic mean roughness value R(2)ₐ is in the range of 1.70-8.00, and particularly preferably in the range of 2.00-8.00.

Surprisingly, it has been found that a substrate arrangement which has a bonding substrate which is designed such that the underside of the bonding substrate (i) has an arithmetic mean roughness value R(1)ₐ along at least one section S1, and (ii) an arithmetic mean roughness value R(2)ₐ along at least one section S2, wherein the at least one section S2 runs perpendicularly to the at least one section S1, wherein the ratio Q of arithmetic mean roughness value R(1)ₐ to arithmetic mean roughness value R(2)ₐ is in the range of 1.70-10.00, allows a particularly stable integrally bonded connection between the bonding substrate and the upper side of the electronic component via the contacting layer.

According to a preferred embodiment, the underside of the bonding substrate comprises a profile with repeating structural units along a first direction, wherein the at least one section S1 extends in the first direction.

The profile with repeating structural units results preferably from making depressions in the underside of the bonding substrate. The repeating structural units can accordingly be, for example, a sequence of depressions. The depressions are preferably made here in a directed manner. The underside of the bonding substrate along the at least one section S1 preferably has an arithmetic mean roughness value R(1)ₐ which differs from the arithmetic mean roughness value R(2)ₐ along at least one section S2, which runs perpendicularly to the at least one section S1.

Preferably, depressions are introduced by rolling the underside of the bonding substrate. A roller is guided here over the upper side of the bonding substrate along a rolling direction. Consequently, the underside of the bonding substrate preferably comprises a rolling profile along a rolling direction, wherein the at least one section S2 extends in the rolling direction.

According to a preferred embodiment, the substrate arrangement is suitable for connection to at least one electronic component. According to a particularly preferred embodiment, the substrate arrangement is suitable for connecting the bonding substrate to at least one electronic component.

An electronic component is preferably understood to mean an electronic or electrical part. The electronic component is preferably selected from the group consisting of semiconductor components. The semiconductor components are preferably selected from the group consisting of transistors, diodes, and integrated circuits.

According to a preferred embodiment, the electronic component comprises a metal upper-side coating. The metal upper-side coating can serve to enable an easier connection of the bonding substrate via the contacting layer to the upper side of the electronic component. It may therefore be preferred that the upper side of the electronic component is created by the metal upper-side coating. The metal upper-side coating of the electronic component preferably comprises silver. According to a preferred embodiment, the electronic component comprises a metal underside coating. The metal underside coating can serve to enable an easier connection of the base substrate to the underside of the electronic component. It may therefore be preferred that the underside of the electronic component is created by the metal underside coating. The metal underside coating of the electronic component preferably comprises at least one noble metal. According to a preferred embodiment, the metal underside coating of the electronic component comprises at least one element which is selected from the group consisting of silver, aluminum, titanium, and nickel, and very particularly preferably silver.

The electrical contacting of the upper side of the electronic component with unpopulated regions of base substrates can preferably be prepared with the substrate arrangement. For this purpose, the bonding substrate is connected in an integrally bonded manner to the upper side of the electronic component via the contacting layer. The bonding substrate provides a surface which is suitable for the integrally bonded connection to a bonding wire, in particular a copper bonding wire, in a particularly stable manner.

The method for producing the substrate arrangement according to the invention is not further limited.

According to a preferred embodiment, the method for producing the substrate arrangement according to the invention comprises the steps of:
(A) providing a metal foil,
(B) treating the metal foil to obtain a bonding substrate comprising an upper side and an underside, wherein the underside of the bonding substrate
   (i) has an arithmetic mean roughness value R(1)ₐ along at least one section S1, and
   (ii) has an arithmetic mean roughness value R(2)ₐ along at least one section S2, wherein the at least one section S2 runs perpendicularly to the at least one section S1,
   wherein the ratio Q of arithmetic mean roughness value R(1)ₐ to arithmetic mean roughness value R(2)ₐ is in the range of 1.70-10.00,
(C) providing a contacting means, and
(D) applying the contacting means to the underside of the bonding substrate to form a contacting layer, wherein the contacting layer is connected to the underside of the bonding substrate in a planar manner at least in regions.

In step (A) of the method, a metal foil is provided.

The metal foil is preferably a metal foil as described elsewhere herein. The metal foil can comprise a coating. On the other hand, the metal foil can also be coating-free.

In step (B) of the method, the metal foil is treated, wherein a bonding substrate is obtained which comprises an upper side and an underside, wherein the underside of the bonding substrate (i) has an arithmetic mean roughness value R(1)ₐ along at least one section S1, and (ii) an arithmetic mean roughness value R(2)ₐ along at least one section S2, wherein the at least one section S2 runs perpendicularly to the at least one section S1, wherein the ratio Q of arithmetic mean roughness value R(1)ₐ to arithmetic mean roughness value R(2)ₐ is in the range of 1.70-10.00.

Depending on the embodiment of the bonding substrate, the procedure can be different in steps (A) and (B).

In the event that the bonding substrate is to comprise a metal foil which comprises a main body and no coating, according to a first embodiment, in step (A), a metal foil can be provided which does not have a coating, and, in step (B), the metal foil can be treated such that at least one side of the uncoated metal foil has a ratio Q of arithmetic mean roughness value R(1)ₐ to arithmetic mean roughness value R(2)ₐ in the range of 1.70-10.00.

In the event that the bonding substrate is to comprise a metal foil which comprises a main body and a coating, according to a second embodiment, in step (A), a metal foil can be provided which comprises a coating, and, in step (B), the coated metal foil can be treated such that preferably the coated side of the metal foil has a ratio Q of arithmetic mean roughness value R(1)ₐ to arithmetic mean roughness value R(2)ₐ in the range of 1.70-10.00.

In the event that the bonding substrate is to comprise a metal foil comprising a main body and a coating, according to a third embodiment, in step (A), a metal foil can be provided which does not comprise a coating, and, in step (B), (i) the uncoated metal foil is treated such that at least one side of the uncoated metal foil has a ratio Q of arithmetic mean roughness value R(1)ₐ to arithmetic mean roughness value R(2)ₐ in the range of 1.70-10.00, and (ii) subsequently a coating is applied to the at least one side of the uncoated metal foil which has a ratio Q of arithmetic mean roughness value R(1)ₐ to arithmetic mean roughness value R(2)ₐ in the range of 1.70-10.00. In this case, the arithmetic mean roughness value R(1)ₐ is and the arithmetic mean roughness value R(2)ₐ are thus preferably determined as described herein for the bonding substrate. The coating is preferably applied such that the ratio Q of arithmetic mean roughness value R(1)ₐ to arithmetic mean roughness value R(2)ₐ remains unchanged, for example by electroplating or chemical deposition. The coating is preferably a coating as described elsewhere herein.

The treatment of the metal foil is not limited further.

In the treatment of the metal foil, depressions are preferably introduced on the underside of the metal foil in order to set a ratio Q of arithmetic mean roughness value R(1)ₐ to arithmetic mean roughness value R(2)ₐ in the range of 1.70-10.00. The impressing of depressions on the underside of the metal foil can in principle be carried out in any manner that is known and appears suitable to a person skilled in the art.

According to a preferred embodiment, the metal foil is treated by a method selected from the group consisting of rolling, brushing, embossing, granulating, notching, stamping, countersinking, grooving, and etching.

According to a particularly preferred embodiment, the metal foil is treated by rolling.

Rolling is preferably understood to mean a processing method in which a material, here the metal foil, is processed between two or more rotating tools. A relief is preferably transferred into the metal foil as a result of the rolling. The rolling can be carried out both as hot rolling and cold rolling. Preferably, the rolling is performed as cold rolling.

According to a preferred embodiment, the rolling is performed by at least one roller.

A roller is preferably understood to mean a substantially cylindrical body. The roller can, in principle, have any desired diameter. Rollers having a diameter in the range of 50-150 mm are preferably suitable for the intended use. Furthermore, the roller should be formed from a material which is harder under operating conditions than the material of the metal foil. Suitable rollers can therefore be formed, for example, from forged steel, hard metal or steel casting.

According to a preferred embodiment, the rolling takes place with an arrangement which comprises at least one roller. Arrangements with a plurality of rollers, for example two or more rollers, are also possible. For example, an arrangement is suitable in which at least two rollers rotate in opposite directions and the metal foil is passed through between the two counter-rotating rollers. The two counter-rotating rollers are arranged such that a spacing is provided between the two rollers. This spacing preferably corresponds to the thickness of the bonding substrate.

The geometry of the rollers is not limited further. The rolling is preferably performed with at least one roller which has a cylindrical surface. The cylindrical surface of the roller preferably has a relief.

The relief is preferably formed by structural units. The structural units preferably result in a pattern. When passing through the metal foil, the pattern of the cylindrical surface of the roller is introduced into the metal foil as a result of the arrangement.

The pattern is preferably characterized by an alternating sequence of elevations along the roller axis or perpendicular to the roller axis. The spacings between the elevations can be adapted in accordance with the desired ratio Q of arithmetic mean roughness value R(1)ₐ to arithmetic mean roughness value R(2)ₐ.

The pattern is furthermore preferably characterized by height differences of the cylindrical surface of the roller. The height difference can likewise be adapted in accordance with the desired ratio Q of arithmetic mean roughness value R(1)ₐ to arithmetic mean roughness value R(2)ₐ. The height difference of the cylindrical surface of the roller may for example be in the range of 2-10 μm. The depth of the depressions introduced into the metal foil depends here on the penetration depth of the relief of the at least one roller into the metal foil. It is possible for the height difference of the relief to be greater than the depressions introduced into the metal foil.

The reshaping of the metal foil with rollers, wherein at least one first roller has a relief which is transmitted to the metal foil during reshaping is also referred to as embossing rolling.

According to a further embodiment, the metal foil is treated by stamping. A stamp is a surface provided with a relief. The relief has a height difference. In principle, all materials that are known and appear suitable to a person skilled in the art, but in particular the same ones as for the rollers, are suitable for a stamp. During stamping, a stamp is lowered onto the metal foil. The relief is thereby pressed into the metal foil until the desired ratio Q of arithmetic mean roughness value R(1)ₐ to arithmetic mean roughness value R(2)ₐ is achieved. Preferably, during the stamping of the metal foil, a further tool or a plate is provided on the side of the metal foil facing away from the stamp and is designed such that the metal foil to be reshaped cannot escape, for example, as a result of the stamp bending. Rather, the metal foil to be reshaped is held in position by the further tool in relation to the stamping direction.

In step (B), a bonding substrate is obtained which comprises an upper side and an underside, wherein the underside of the bonding substrate (i) has an arithmetic mean roughness value R(1)ₐ along at least one section S1, and (ii) an arithmetic mean roughness value R(2)ₐ along at least one section S2, wherein the at least one section S2 runs perpendicularly to the at least one section S1, wherein the ratio Q of arithmetic mean roughness value R(1)ₐ to arithmetic mean roughness value R(2)ₐ is in the range of 1.70-10.00.

The bonding substrate obtained in step (B) can comprise a metal foil. The bonding substrate can be a metal foil. According to a preferred embodiment, the bonding substrate preferably comprises a metal foil which comprises a main body on which a coating can be arranged, wherein the underside of the bonding substrate (i) is created by the main body when no coating is arranged on the main body, and (ii) is created by the coating when there is a coating arranged on the main body.

In step (C1) of the method, a contacting means is provided.

The contacting means is preferably a contacting means as described elsewhere herein.

In step (D) of the method, the contacting means is applied to the underside of the bonding substrate to form a contacting layer, wherein the contacting layer is connected to the underside of the bonding substrate in a planar manner at least in regions.

Applying the contacting material to the underside of the bonding substrate to form a contacting layer can be carried out by methods customary in the art. Preferably, the contacting material is applied by jetting, dispensing, spraying, brushing, dabbing, dipping or printing, in particular screen printing or stencil printing.

According to a preferred embodiment, in a further step (E), a prefixing agent is applied to the contacting layer and/or to regions of the underside of the bonding substrate not provided with the contacting layer to form a prefixing layer, wherein the prefixing layer is connected to the contacting layer and/or to regions of the bonding substrate not provided with the contacting layer. The prefixing agent is preferably a prefixing agent as described elsewhere herein. The prefixing agent can be applied to the contacting layer by methods customary in the art. Preferably, the prefixing agent is applied by jetting, dispensing, spraying, brushing, dabbing, dipping or printing, in particular screen printing or stencil printing.

According to a preferred embodiment, pre-drying takes place in a further step (F) of the method. The pre-drying can serve to at least partially remove volatile constituents, such as an organic compound, for example, contained in the contacting material and, if present, in the prefixing agent. The pre-drying can take place, for example, at a temperature in the range of 80-150° C. and, for example, for a period of 2-30 minutes. The pre-drying usually results in a volume shrinkage, so that the thickness of the contacting layer and, if present, of the prefixing layer is also reduced.

In the method, a substrate arrangement is obtained with which the bonding substrate can be connected in a particularly stable and integrally bonded manner to the upper side of an electronic component via the contacting layer.

The invention relates to a method for producing an electronic assembly.

The method comprises the following steps:
(A) providing a base substrate having an upper side, wherein the base substrate comprises a metal layer,
(B) providing an electronic component having an upper side and an underside,
(C) providing a substrate arrangement,
(D) contacting the upper side of the base substrate with the underside of the electronic component, forming an integrally bonded connection and
(E) contacting the upper side of the electronic component with the contacting layer of the substrate arrangement, forming an integrally bonded connection.

In step (A) of the method, a base substrate is provided. The base substrate comprises a metal layer. Furthermore, the base substrate has an upper side.

For example, the metal layer of the base substrate can comprise copper. Preferably, the metal layer of the base substrate can be formed from a metal foil. According to a preferred embodiment, the metal layer of the base substrate comprises a copper foil.

According to a preferred embodiment, the base substrate consists of the metal layer.

According to another preferred embodiment, the base substrate comprises a metal layer and a layer of insulating material. According to a further preferred embodiment, the base substrate comprises a metal layer and a layer of insulating material which are connected to one another in an integrally bonded manner. The base substrate preferably comprises a layer of insulating material which, on a first side and a second side facing away from the first side, is connected in an integrally bonded manner to a metal layer.

The insulating material of the base substrate is preferably selected from the group consisting of glass and ceramic. The ceramic can, for example, be selected from the group consisting of oxide ceramics, nitride ceramics, and carbide ceramics.

According to a preferred embodiment, the base substrate is selected from the group consisting of metal-ceramic substrates, printed circuit boards (PCBs) and leadframes. According to a particularly preferred embodiment, the base substrate is a metal-ceramic substrate customary in the art. The metal-ceramic substrate is preferably selected from the group consisting of DCB (direct copper bonded) substrates and AMB (active metal brazed) substrates.

The upper side of the base substrate is preferably created by the metal layer.

In step (B) of the method, an electronic component is provided. The electronic component has an upper side and an underside.

The electronic component is preferably an electronic component as described elsewhere herein.

In step (C) of the method, a substrate arrangement is provided.

The substrate arrangement is preferably a substrate arrangement as described elsewhere herein.

The substrate arrangement therefore preferably has
(a) a bonding substrate comprising an upper side and an underside, and
(b) a contacting layer which comprises a contacting means, wherein the contacting layer is connected in a planar manner to the underside of the bonding substrate at least in regions,
wherein the underside of the bonding substrate
(i) has an arithmetic mean roughness value R(1)ₐ along at least one section S1, and
(ii) has an arithmetic mean roughness value R(2)ₐ along at least one section S2, wherein the at least one section S2 runs perpendicularly to the at least one section S1,
wherein the ratio Q of arithmetic mean roughness value R(1)ₐ to arithmetic mean roughness value R(2)ₐ is in the range of 1.70-10.00.

In step (D) of the method, the upper side of the base substrate is contacted with the underside of the electronic component, forming an integrally bonded connection.

For this purpose, the base substrate and the electronic component are preferably positioned such that the underside of the electronic component is in contact with the upper side of the base substrate preferably via a contacting material. The contacting means can be, for example, a contacting means as described elsewhere herein in relation to the substrate arrangement. Consequently, the contacting material can, for example, be a sintering paste, a solder paste or a conductive adhesive. The structure comprising the base substrate and the electronic component is subsequently subjected to a treatment which allows an integrally bonded connection through the contacting material. The underside of the electronic component is fastened here to the upper side of the base substrate.

In step (E) of the method, the upper side of the electronic component is contacted with the contacting layer of the substrate arrangement, forming an integrally bonded connection. In this case, the formation of an integrally bonded connection is preferably carried out between the upper side of the electronic component and the bonding substrate.

For this purpose, the substrate arrangement and the electronic component are preferably positioned such that the contacting layer of the substrate arrangement is in contact with the upper side of the electronic component. The structure comprising the substrate arrangement and the electronic component is subsequently subjected to a treatment which allows an integrally bonded connection through the contacting material of the contacting layer. The bonding substrate of the substrate arrangement is fastened here to the upper side of the electronic component.

Steps (D) and (E) can be carried out in one manufacturing step or in different manufacturing steps. In this case, steps (D) and (E) can be carried out sequentially or simultaneously.

If steps (D) and (E) are carried out sequentially, step (D) can take place before step (E). On the other hand, it is also possible for step (E) to take place before step (D).

If steps (D) and (E) are carried out sequentially, according to a first embodiment in step (D) the electronic component can be part of a first arrangement which comprises the electronic component and the bonding substrate. In this case, a first arrangement, which comprises the electronic component and the bonding substrate, can first be produced in step (E) by contacting the upper side of the electronic component with the contacting layer of the substrate arrangement, forming an integrally bonded connection between the upper side of the electronic component and the bonding substrate. This first arrangement can then be contacted with the base substrate in step (D) so that the underside of the electronic component is connected in an integrally bonded connection to the upper side of the base substrate as part of the first arrangement.

If steps (D) and (E) are carried out sequentially, according to a second embodiment in step (E) the electronic component can be part of a second arrangement which comprises the base substrate and the electronic component. In this case, a second arrangement which comprises the base substrate and the electronic component can first be produced in step (D). This second arrangement can then be contacted with the substrate arrangement in step (E) so that the underside of the bonding substrate is connected in an integrally bonded manner to the upper side of the electronic component as part of the second arrangement.

By means of the integrally bonded connection of the base substrate, electronic component, and bonding substrate, an electronic assembly is obtained.

According to a preferred embodiment, in a further step (F) a region on the upper side of the bonding substrate is electrically contacted with a region on the upper side of the base substrate. The electrical contacting preferably takes place by wire bonding. A bonding wire is preferably used for the wire bonding. The bonding wire preferably comprises copper. According to a preferred embodiment, the bonding wire is made of a material selected from the group consisting of copper and copper alloys.

### DESCRIPTION OF THE METHOD

To determine the mean roughness value R(1)ₐ and the mean roughness value R (2) a, 3D images of the surface that comprised the respective reference sections S1 and S2 were taken using the confocal microscope μsurf custom (NanoFocus AG, Germany) on the underside of the bonding substrate. By means of the software μSoft Analysis Premium (7.4.8872; NanoFocus AG, Germany), the microscopic 3D images were analyzed. For this purpose, any deflection of the bonding substrate in the 3D images was initially corrected (use of a polynomial of degree 2). The reference sections S1 and S2 (for example, with a width of 0.0315 mm) were then defined and the roughness profile along the reference sections S1 and S2 was obtained using a Gaussian filter (0.8 mm). In each case, at least ten reference sections S1 of the same length running in parallel with one another and at least ten reference sections S2 of the same length running in parallel with one another were selected, wherein the reference sections S2 in each case run perpendicularly to the reference sections S1. In this case, the reference sections S1 had a length of at least 20% of the circumference of the bonding substrate. The reference sections S2 had a length of at least 50% of the length of the reference sections S1. From the roughness profiles obtained along the reference sections S1 and S2, the mean roughness value R(1)ₐ and the mean roughness value R(2)ₐ were determined according to the version of the standard DIN EN ISO 4287 valid at the filing date.

### DESCRIPTION OF THE FIGURES

Further features and advantages of the invention can be found in the following description, in which preferred embodiments of the invention are explained with reference to schematic drawings.

In the drawings:

FIG. 1 shows the side view of a substrate arrangement according to the invention;

FIG. 2 shows the side view of a substrate arrangement according to the invention; and

FIG. 3 shows the side view of an electronic assembly which is obtained by the method according to the invention.

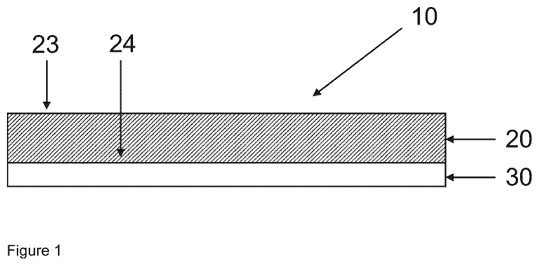

FIG. 1 shows a substrate arrangement 10 according to the invention, which comprises a bonding substrate 20 and a contacting layer 30. The bonding substrate 20 has an upper side 23 and an underside 24. The contacting layer 30 is connected in a planar manner to the underside 24 of the bonding substrate 20. The underside 24 of the bonding substrate 20 has: (i) an arithmetic mean roughness value R(1)ₐ along at least one section S1 and (ii) an arithmetic mean roughness value R(2)ₐ along at least one section S2, wherein the at least one section S2 runs perpendicularly to the at least one section S1, and wherein the ratio Q of arithmetic mean roughness value R(1)ₐ to arithmetic mean roughness value R(2)ₐ is in the range of 1.70-10.00.

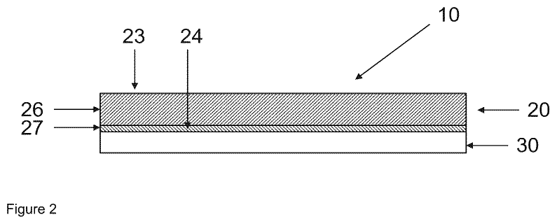

FIG. 2 shows a substrate arrangement 10 according to the invention, which comprises a bonding substrate 20 and a contacting layer 30. The bonding substrate 20 comprises a metal foil which comprises a main body 26 on which a coating 27 is arranged. The underside 24 of the bonding substrate 20 is created by the coating 27 and the upper side 23 of the bonding substrate 20 is created by the main body 26 of the metal foil. The underside 24 of the bonding substrate 20 has: (i) an arithmetic mean roughness value R(1)ₐ along at least one section S1 and (ii) an arithmetic mean roughness value R(2)ₐ along at least one section S2, wherein the at least one section S2 runs perpendicularly to the at least one section S1, and wherein the ratio Q of arithmetic mean roughness value R(1)ₐ to arithmetic mean roughness value R(2)ₐ is in the range of 1.70-10.00.

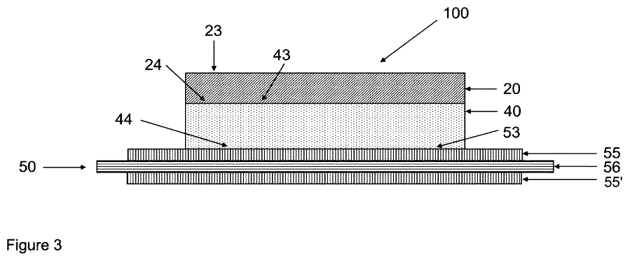

FIG. 3 shows an electronic assembly 100 which can be produced by the method according to the invention. The electronic assembly 100 comprises a bonding substrate 20, an electronic component 40, and a base substrate 50. The base substrate 50 has a layer of insulating material 56 which is connected on both sides to a metal layer 55, 55′ in a planar manner. The base substrate 50 is typically a metal-ceramic substrate. The upper side 53 of the base substrate 50 is created by the metal layer 55. An electronic component 40, which has an upper side 43 and an underside 44, is arranged on the upper side 53 of the base substrate 50. The underside 44 of the electronic component 40 is arranged on the upper side 53 of the base substrate 50. The electronic component 40 is connected to the base substrate 50 in a planar manner. For this purpose, the electronic component 40 can be fastened to the base substrate 50, for example using a sintering paste. A sintering layer (not shown) can therefore be located between the upper side 53 of the base substrate 50 and the underside 44 of the electronic component 40. The electronic component 40 is connected to a bonding substrate 20. The bonding substrate 20 has an upper side 23 and an underside 24. The underside 24 of the bonding substrate 20 is arranged on the upper side 43 of the electronic component 40. The bonding substrate 20 is fastened to the electronic component 40. The fastening takes place by first positioning a substrate arrangement comprising the bonding substrate 20 and a contacting layer on the upper side 43 of the electronic component 40 such that the contacting layer is in contact with the upper side 43 of the electronic component 40. The structure thus obtained is then exposed to conditions which enable the formation of an integrally bonded connection between the bonding substrate 20 and the electronic component 40. The contacting layer can consist, for example, of a pre-dried sintering paste. In this case, the structure is subjected to temperature and pressure in order to enable the formation of a sintered connection between the bonding substrate 20 and the electronic component 40. The electronic assembly 100 then comprises a sintered layer (not shown) between the bonding substrate 20 and the electronic component 40. The upper side 23 of the bonding substrate 20 can be contacted with a bonding wire with unpopulated regions on the upper side 53 of the base substrate 50 (not shown). The upper side 23 of the bonding substrate 20 can also be connected in an integrally bonded manner to a further component, in particular using a sintering material (not shown).

### EXAMPLES

### Production of Substrate Arrangements—Example 1:

A copper foil having a thickness of 50 μm was used to produce a substrate arrangement according to Example 1. The copper foil was rolled so that the underside of the copper foil had an arithmetic mean roughness value R(1)ₐ, an arithmetic mean roughness value R(2)ₐ, and a ratio Q of arithmetic mean roughness value R(1)ₐ to arithmetic mean roughness value R(2)ₐ according to Table 1. The arithmetic mean roughness value R(1)ₐ and the arithmetic mean roughness value R(2)ₐ were determined as described above. The copper foil was structured by means of photolithographic etching using a suitable masking with an iron chloride (FeCl₃) etching solution in copper foil pieces of the dimensions 4 mm×8 mm, wherein the individual copper foil pieces were still connected to one another via webs. The masking was then removed. As a result, bonding substrates connected to one another via webs were obtained, each of which had an upper side and an underside, wherein the underside of the bonding substrates had an arithmetic mean roughness value R(1)ₐ, an arithmetic mean roughness value R(2)ₐ, and a ratio Q of arithmetic mean roughness value R(1)ₐ to arithmetic mean roughness value R(2)ₐ according to Table 1.

The underside of the bonding substrates was then provided with a contacting layer. For this purpose, a sintering paste (ASP 338-28, Heraeus) was applied by means of stencil printing to a region of 3 mm×3 mm on the underside of the bonding substrates (wet layer thickness of 50 μm). Apart from the region provided with sintering paste, the underside of the bonding substrates had a free region of 4.0 mm×4.5 mm in addition to a circumferential edge region of 0.5 mm width that was free of sintering paste. The bonding substrates thus provided with a contacting layer were then dried at 100° C. in an air atmosphere for ten minutes and singularized with separation of the webs by means of laser, wherein substrate arrangements according to Example 1 were obtained.

### Production of Substrate Arrangements—Examples 2-7 and Comparative Examples 1-4

The substrate arrangements of Examples 2-7 and Comparative Examples 1~4 were prepared analogously to the substrate arrangement of Example 1, wherein, however, the arithmetic mean roughness value R(1)ₐ, the arithmetic mean roughness value R(2)ₐ, and the ratio Q of arithmetic mean roughness value R(1)ₐ to arithmetic mean roughness value R(2)ₐ according to Table 1 were varied. For this purpose, commercially available copper foils were sometimes used. Sometimes the arithmetic mean roughness value R(1)ₐ, the arithmetic mean roughness value R(2)ₐ, and the ratio Q of arithmetic mean roughness value R(1)ₐ to arithmetic mean roughness value R(2)ₐ were set by varying the rolling process (use of rollers with different patterns, sequences of elevations on the roller and height differences of the cylindrical surface of the roller), so that different profiles were obtained on the underside of the copper foils.

### Production of Electronic Assemblies—Example 1

To produce an electronic assembly, an arrangement consisting of a base substrate and an electronic component was first created. A commercially available direct-metallized copper-ceramic substrate (DCB; Condura® classic, Heraeus) and, as an electronic component, a silicon chip having the dimensions 4 mm×4 mm (thickness=250 μm), which had a metallization on the underside (100 nm aluminum, 50 nm titanium, 100 nm nickel, and lastly 700 nm silver) and a metallization (700 nm silver) on the upper side, was used as the base substrate.

A sintering paste (ASP 338-28, Heraeus) was applied to the upper side of the copper-ceramic substrate by means of stencil printing (wet layer thickness=100 μm). The copper-ceramic substrate provided with sintering paste was dried at 100° C. for ten minutes in an air atmosphere and then cooled. The silicon chip was positioned on the pre-dried sintering paste so that the underside of the silicon chip was in contact with the upper side of the copper-ceramic substrate.

Subsequently, the substrate arrangement according to Example 1 was positioned on the upper side of the silicon chip, so that the contacting layer of the substrate arrangement was in contact with the upper side of the silicon chip. The free region on the underside of the bonding substrate projected beyond the upper side of the silicon chip.

The structure obtained was then sintered. The sintering was carried out in a PINK sintering press (Pink, Wertheim) for a period of three minutes in a nitrogen atmosphere at a pressure of 20 MPa and a temperature of 250° C. An electronic assembly was obtained.

### Production of Electronic Assemblies—Examples 2-7 and Comparative Examples 1-4

Electronic assemblies were also produced using the substrate arrangements of Examples 2-7 and Comparative Examples 1-4. This was done analogously to the production of the electronic assembly with the substrate arrangement from Example 1.

### Test for Adhesive Strength:

The electronic assemblies produced with the substrate arrangements of Examples 1-7 and Comparative Examples 1~4 were investigated with respect to the adhesive strength of the bonding substrates on the upper side of the silicon chips. By means of a material testing machine from ZwickRoell (500 N, ZwickRoell GmbH & Co KG), the force was measured which had to be applied in order to remove from the upper side of the silicon chips the bonding substrates connected in an integrally bonded manner to the upper side of the silicon chips. For this purpose, the electronic assemblies produced with the substrate arrangements of Examples 1-7 and Comparative Examples 1~4 were clamped into a hold-down device, the free regions projecting beyond the upper side of the silicon chips were fixed on the underside of the bonding substrates in a screw tensioning device and removed at a peel-off angle of 90° at a speed of 50 mm/min. The adhesive strength was then applied on a scale of ++ (very high adhesive strength) to −− (very low adhesive strength). The results are shown in Table 1.

TABLE 1
Analysis of Examples 1-7 and Comparative Examples 1-4.

| | R(1)ₐ | R(2)ₐ | Q (R(1)ₐ/ | Adhesive |
|---|---|---|---|---|
| | (in μm) | (in μm) | R(2)ₐ) | strength |
| Examples | | | | |
| 1 | 0.53 | 0.12 | 4.42 | ++ |
| 2 | 0.33 | 0.14 | 2.36 | + |
| 3 | 0.32 | 0.11 | 2.91 | + |
| 4 | 0.52 | 0.30 | 1.73 | + |
| 5 | 0.42 | 0.14 | 3.00 | + |
| 6 | 0.65 | 0.13 | 5.00 | ++ |
| 7 | 0.54 | 0.25 | 2.16 | + |
| Comparative examples | | | | |
| 1 | 0.16 | 0.11 | 1.45 | − |
| 2 | 0.11 | 0.07 | 1.57 | − |
| 3 | 0.15 | 0.09 | 1.67 | − |
| 4 | 2.36 | 0.21 | 11.24 | − |

The results show that with the substrate arrangements of Examples 1-7 according to the invention, a particularly stable integrally bonded connection between the bonding substrate and the upper side of an electronic component can be achieved via a contacting layer. The integrally bonded connection is more stable here compared to an integrally bonded connection which is obtained with the substrate arrangements of Comparative Examples 1-4.

### LIST OF REFERENCE NUMERALS

10 substrate arrangement
20 bonding substrate
23 upper side (bonding substrate)
24 underside (bonding substrate)
26 main body
27 coating
30 contacting layer
40 electronic component
43 upper side (electronic component)
44 underside (electronic component)
50 base substrate
53 upper side (base substrate)
55,55′ metal layer
56 layer of insulating material
100 electronic assembly

1. A substrate arrangement comprising
(a) a bonding substrate comprising an upper side and an underside, and
(b) a contacting layer which comprises a contacting means, wherein the contacting layer is connected in a planar manner to the underside of the bonding substrate at least in regions, wherein the underside of the bonding substrate
(i) has an arithmetic mean roughness value R(1)ₐ along at least one section S1, and
(ii) has an arithmetic mean roughness value R(2)ₐ along at least one section S2, wherein the at least one section S2 runs perpendicularly to the at least one section S1, wherein the ratio Q of arithmetic mean roughness value R(1)ₐ to arithmetic mean roughness value R(2)ₐ is in the range of 1.70-10.00.

2. The substrate arrangement according to claim 1, wherein the underside of the bonding substrate comprises a profile with repeating structural units along a first direction, wherein the at least one section S1 extends in the first direction.

3. The substrate arrangement according to claim 1, wherein the underside of the bonding substrate comprises a rolling profile along a rolling direction, wherein the at least one section S2 extends in the rolling direction.

4. The substrate arrangement according to claim 1, wherein the bonding substrate comprises a metal foil.

5. The substrate arrangement according to claim 4, wherein the metal foil comprises copper.

6. The substrate arrangement according to claim 4, wherein the metal foil comprises a main body and a coating.

7. The substrate arrangement according to claim 6, wherein the underside of the bonding substrate is created by the coating.

8. The substrate arrangement according to claim 6, wherein the coating comprises a noble metal.

9. The substrate arrangement according to claim 1, wherein the contacting means comprises a sintering material.

10. The substrate arrangement according to claim 9, wherein the sintering material comprises at least one element selected from the group consisting of silver and copper.

11. The substrate arrangement according to claim 9, wherein the sintering material comprises a sintering paste.

12. The substrate arrangement according to claim 11, wherein the sintering paste is pre-dried.

13. The substrate arrangement according to claim 1, wherein the ratio Q of arithmetic mean roughness value R(1)ₐ to arithmetic mean roughness value R(2)ₐ is in the range of 1.70-8.00.

14. The substrate arrangement according to claim 1, wherein the substrate arrangement is designed for connection to at least one electronic component.

15. A method for producing an electronic assembly comprising the steps of
(A) providing a base substrate having an upper side, wherein the base substrate comprises a metal layer,
(B) providing an electronic component having an upper side and an underside, and
(C) providing a substrate arrangement according to claim 1,
(D) contacting the upper side of the base substrate with the underside of the electronic component, forming an integrally bonded connection and
(E) contacting the upper side of the electronic component with the contacting layer of the substrate arrangement, forming an integrally bonded connection.

16. The substrate arrangement according to claim 2, wherein the underside of the bonding substrate comprises a rolling profile along a rolling direction, wherein the at least one section S2 extends in the rolling direction.

17. The substrate arrangement according to claim 2, wherein the bonding substrate comprises a metal foil.

18. The substrate arrangement according to claim 3, wherein the bonding substrate comprises a metal foil.

19. The substrate arrangement according to claim 5, wherein the metal foil comprises a main body and a coating.

20. The substrate arrangement according to claim 7, wherein the coating comprises a noble metal.
